(19) United States
(12) Patent Application Publication
(10) Pub. No.: US 2020/0181770 A1
(43) Pub. Date: Jun. 11, 2020

(54) METHOD OF FORMING A STRUCTURE INCLUDING SILICON NITRIDE ON TITANIUM NITRIDE AND STRUCTURE FORMED USING THE METHOD

(71) Applicant: ASM IP Holding B.V., Almere (NL)

(72) Inventors: Delphine Longrie, Ghent (BE); Fu Tang, Gilbert, AZ (US)

(21) Appl. No.: 16/210,922

(22) Filed: Dec. 5, 2018

(51) Int. Cl. C23C 16/34; H01L 21/02; C23C 16/455

(52) U.S. Cl. CPC C23C 16/345; H01L 21/02186; H01L 29/513; H01L 21/0228; C23C 16/45525; H01L 21/0217

(57) ABSTRACT

A method of forming a structure including a silicon nitride overlying a titanium nitride layer is disclosed. The method includes forming the titanium nitride layer and the silicon nitride layer in the same reaction chamber—e.g., without a vacuum break—to mitigate oxidation of the titanium nitride layer that might otherwise occur.

### FIELD OF THE DISCLOSURE

The present disclosure generally relates to thin-film deposition methods and structures. More particularly, the disclosure relates to methods of forming silicon nitride capping layers on titanium nitride films and to structures including such layers and films.

### BACKGROUND OF THE DISCLOSURE

Titanium nitride films can be used as a metal or conducting layer in a variety of applications. For example, titanium nitride films can be used as a metal layer in a metal oxide semiconductor (MOS) device or a structure forming part of such device. Use of the titanium nitride film or layer in such structures may be desirable, particularly in cases in which a channel region of the MOS device includes silicon germanium, because the titanium nitride layer exhibits oxygen-scavenging properties, which can be desirable to reduce interface trapped charge density (Dit) across a band gap of such structures and/or reduce equivalent oxide thickness (EOT). Titanium nitride layers can also be used as work function layers in MOS devices.

Titanium nitride films readily oxidize, forming titanium oxynitride, when exposed to oxidizing environment, such as substrate transfer areas or a front end unified or universal pods (FOUP) that may include water vapor and/or oxygen. The titanium oxynitride films exhibit a higher resistivity than titanium nitride films, and thus are generally less desirable for metal films of a MOS device. Further, the oxygen-scavenging properties of the titanium oxynitride film are diminished, relative to the oxygen-scavenging properties of the titanium nitride film.

To mitigate oxidation of titanium nitride films, efforts are made to mitigate exposure of substrates including the titanium nitride films to oxidizing environments prior to subsequent processing. Providing nitrogen to a transfer module of a processing tool, sealing a substrate load/unload area of the processing tool, and use of a FOUP that is purged with nitrogen, can be used to mitigate exposure of the substrates including titanium nitride films to an oxidizing environment. However, such procedures are relatively expensive and require modifications to processing tools to provide adequate sealing. Further, such techniques can still allow undesirable amounts of oxidation of the titanium nitride material prior to subsequent processing. Accordingly, improved methods for maintaining desirable properties of titanium nitride films while mitigating any added expense or complexity to substrate processing are desired.

### SUMMARY OF THE DISCLOSURE

Various embodiments of the present disclosure relate to methods of mitigating undesired oxidation of titanium nitride films. While the ways in which various embodiments of the present disclosure address drawbacks of prior methods are discussed in more detail below, in general, various embodiments of the disclosure provide in situ methods of capping the titanium nitride layer with material less prone to oxidation and/or that mitigates oxidation of the titanium nitride film.

In accordance with exemplary embodiments of the disclosure, a method of forming a structure includes providing a substrate in a reaction chamber, forming a layer comprising titanium nitride overlying the substrate in the reaction chamber, and forming a layer comprising silicon nitride overlying the layer comprising titanium nitride in the reaction chamber. The step of forming the layer comprising titanium nitride and the step of forming the layer comprising silicon nitride are performed within the same reaction chamber—e.g., without exposing the substrate to another intervening environment (e.g., a substrate transfer region of a processing tool or the like) or exposing the substrate to an intervening vacuum break. The step of forming the layer comprising silicon nitride can include a cyclic deposition step, such as atomic layer deposition. In accordance with various aspects of these embodiments, the step of forming the layer comprising silicon nitride can be self-limiting, i.e., the growth of the silicon nitride layer can substantially stop after the silicon nitride layer reaches a certain thickness—e.g., about 2 Angstroms in some cases. In accordance with further aspects, a thickness of the silicon nitride layer is greater than 0 and less than 5 Angstroms. Because the titanium nitride and the silicon nitride layers are deposited in the same reaction chamber, the deposition conditions (e.g., pressure, temperature) can be about the same (e.g., within ten, five, two, one, or one half of a percent). The titanium nitride layer can be formed over high dielectric constant material, such as hafnium oxide and/or work function layers, such as titanium carbide, titanium aluminum carbide, or the like. In accordance with yet additional aspects of these embodiments, the step of forming the layer comprising titanium nitride and the step of forming the layer comprising silicon nitride can be repeated, individually and/or collectively, a number of times to form a laminate structure formed from deposited layers of titanium nitride and silicon nitride.

In accordance with additional embodiments of the disclosure, a structure including a titanium nitride layer and a silicon nitride layer is formed according to a method disclosed herein. Exemplary structures can include, for example, a channel region (e.g., a silicon germanium channel region), a high dielectric constant layer (e.g., comprising a high dielectric constant material as described herein) overlying the channel region, a layer comprising titanium nitride layer overlying the high dielectric constant layer, and a silicon nitride layer formed overlying (e.g., in contact with) the titanium nitride layer.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with at least one exemplary embodiment of the present disclosure.

FIG. 2 illustrates a structure in accordance with at least one exemplary embodiment of the present disclosure.

FIG. 3 illustrates another structure in accordance with at least one embodiment of the disclosure.

It will be appreciated that elements in the figures are illustrated for simplicity and clarity and have not necessarily been drawn to scale. For example, the dimensions of some of the elements in the figures may be exaggerated relative to other elements to help to improve the understanding of illustrated embodiments of the present disclosure.

### DETAILED DESCRIPTION OF EXEMPLARY EMBODIMENTS OF THE DISCLOSURE

The description of exemplary embodiments provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. Further, the illustrations presented herein are not meant to be actual views of any particular material, structure, or device, but are merely idealized representations that are used to describe embodiments of the disclosure.

The present disclosure generally relates to methods of forming structures and to structures formed using the methods. As set forth in more detail below, the methods and structures described herein can be used to form, for example, MOS devices having high-mobility channel material (e.g., silicon germanium) with relatively low interface trapped charge density and/or relatively low equivalent oxide thickness, compared to structures and devices formed using other techniques. Further, exemplary methods can be used to form structures that include a titanium nitride layer and maintain the relatively low resistance and/or relatively high oxygen-scavenging properties of the titanium nitride layer.

As used herein, a layer including titanium nitride can comprise, consist essentially of, or consist of titanium nitride material (with or without a dopant). Films consisting of titanium nitride (with or without a dopant) can include an acceptable amount of impurities, such as carbon and/or chlorine that may originate from one or more precursors used to deposit the titanium nitride layers.

Similarly, a layer including silicon nitride can comprise, consist essentially of, or consist of silicon nitride material. Films consisting of silicon nitride can include an acceptable amount of impurities, such as carbon, chlorine, and/or hydrogen, that may originate from one or more precursors used to deposit the silicon nitride layers.

As used herein, the term substrate may refer to any underlying material or materials upon which material can be deposited. Exemplary substrates can be used to form a device, a circuit, or a structure. By way of examples, a substrate can be or include semiconductor material, such as but not limited to, silicon (Si), silicon oxide (e.g., SiO₂), germanium (Ge), germanium oxide (e.g., GeO₂), germanium tin (GeSn), silicon germanium (SiGe), silicon germanium tin (SiGeSn), silicon carbide (SiC), or a group III-V semiconductor material, such as, for example, gallium arsenide (GaAs), gallium phosphide (GaP), gallium nitride (GaN), and other materials, such as titanium aluminum nitride (TiAlN), aluminum nitride (AlN), aluminum oxide (Al₂O₃), aluminum carbide (e.g., Al₄C₃), hafnium oxide (HfO₂), titanium carbide (TiC), and titanium aluminum carbide (TiAlC). In some embodiments of the disclosure, the substrate 202 may comprise an engineered substrate wherein a surface semiconductor layer is disposed over a bulk support with an intervening buried oxide (BOX) disposed there between. The substrate can be patterned. Patterned substrates may comprise substrates that may include semiconductor device structures formed into or onto a surface of the substrate; for example, a patterned substrate may comprise partially fabricated semiconductor device structures, such as, for example, transistors and/or memory elements. In some embodiments, the substrate may contain monocrystalline surfaces and/or one or more secondary surfaces that may comprise a non-monocrystalline surface, such as a polycrystalline surface and/or an amorphous surface. Monocrystalline surfaces may comprise, for example, one or more of silicon (Si), silicon germanium (SiGe), germanium tin (GeSn), or germanium (Ge). Polycrystalline or amorphous surfaces may include dielectric materials, such as oxides, oxynitrides, nitrides, or carbides, such as, for example, silicon oxides and silicon nitrides. By way of particular examples and as set forth in more detail below, a substrate as described herein can include a silicon germanium (SiGe) (e.g., channel) region, and high dielectric constant material (e.g., one or more of hafnium oxide (HfO₂), lanthanum silicate (LaSiOx), aluminum silicate (e.g., Al₂SiO₅), niobium oxide (NbOx), zirconium oxide (e.g., ZrO₂), hafnium silicate (HfSiO₄), zirconium silicate (ZrSiO₄), or the like); additionally or alternatively, the substrate can include a work function layer, such as titanium carbide (TiC), titanium aluminum carbide (TiAlC), titanium aluminum nitride (TiAlN), or tantalum nitride (TaN).

As used herein, SiGe refers to a silicon germanium alloy SixGe1-x, where x is greater than 0 and less than 1. For example, x can range from about 0.1 to about 0.9.

As used herein, the term cyclic deposition may refer to the sequential introduction of one or more precursors (reactants) into a reaction chamber to deposit a film over a substrate and includes deposition techniques such as atomic layer deposition and cyclical chemical vapor deposition.

As used herein, the term atomic layer deposition (ALD) may refer to a vapor deposition process in which deposition cycles, for example, a plurality of consecutive deposition cycles, are conducted in a reaction chamber. Typically, during each cycle, a first precursor is chemisorbed to a deposition surface (e.g., a substrate surface or a previously deposited underlying material, such as material from a previous ALD cycle), forming a monolayer or sub-monolayer that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. The term atomic layer deposition, as used herein, is also meant to include processes designated by related terms such as, chemical vapor atomic layer deposition, atomic layer epitaxy (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the terms layer, film and thin film may refer to any continuous or non-continuous structures and material formed by the methods disclosed herein. For example, layer, film and thin film could include 2D materials, nanolaminates, nanorods, nanotubes, or nanoparticles, or even partial or full molecular layers, or partial or full atomic layers or clusters of atoms and/or molecules. Layer, film, and thin film may comprise material or a layer with pinholes, but still be at least partially continuous.

As used herein, SiN or silicon nitride refers to a compound that includes silicon and nitrogen. SiN can be represented as SiNₓ, where x varies from, for example, about 0.5 to about 2.0, where some Si—N bonds are formed. In some cases, x may vary from about 0.9 to about 1.7, from about 1.0 to about 1.5, or from about 1.2 to about 1.4. In some embodiments, silicon nitride is formed where Si has an oxidation state of +IV and the amount of nitride in the material may vary.

Similarly, TiN or titanium nitride refers to a compound that can be represented as TiNₓ, where x varies from about 0.5 to about 2.0, as long as some Ti—N bonds are formed. In some cases, x may vary from about 0.5 to about 1.5, from about 0.8 to about 1.2, or from about 0.9 to about 1.1. In some embodiments, titanium nitride is formed where Ti has an oxidation state of +II, +III, or +IV and the amount of nitride in the material may vary.

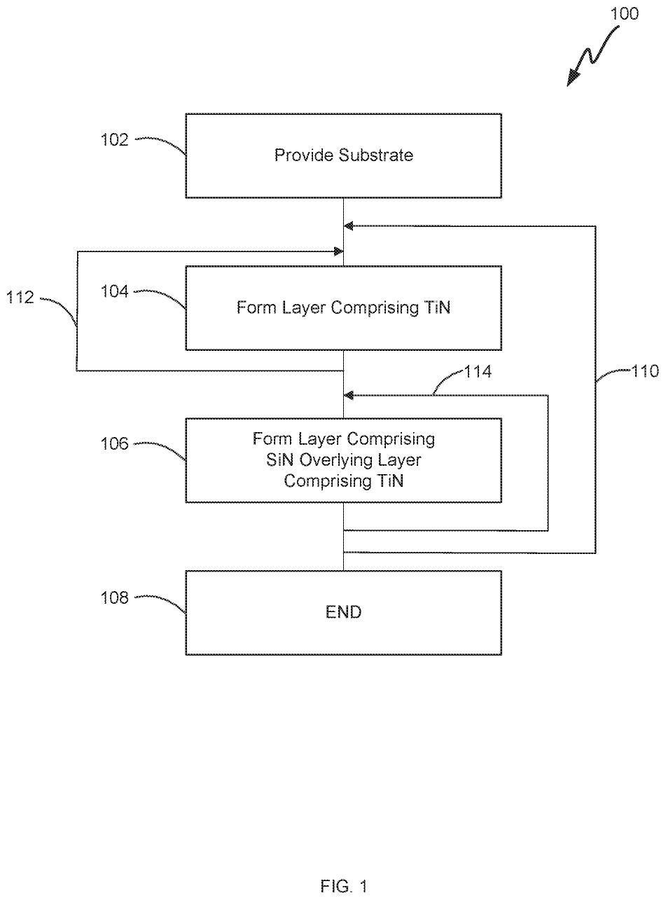

Turning now to the figures, FIG. 1 illustrates a method of forming a structure 100 in accordance with exemplary embodiments of the disclosure. Method of forming a structure 100 includes the steps of providing a substrate in a reaction chamber (step 102), forming a layer comprising titanium nitride overlying the substrate in the reaction chamber (step 104), and forming a layer comprising silicon nitride overlying the layer comprising titanium nitride in the reaction chamber (step 106). As illustrated in FIG. 1, step 104 and/or step 106 can be repeated a number of times (illustrated as loops 112 and 114) before proceeding to the next step. Further, a combination of steps 104 and 106 can be repeated a desired number of times (loop 110). As set forth in more detail below, steps 104 and 106 are performed within the same reaction chamber to mitigate any oxidation of a titanium nitride layer formed during step 104.

Step 102 includes providing a substrate in a reaction chamber. During step 102, a reaction chamber of a reactor can be brought to a desired deposition pressure and temperature for step 104. By way of examples, once a substrate is loaded onto a reaction chamber, a temperature of the reaction chamber and/or a temperature of a susceptor within the reaction chamber can be about 350° C. to about 650° C., or about 400° C. to about 625° C., or about 390° C. to about 450° C., or about 450° C. to about 600° C., or about 300° C. to about 400° C. A pressure within the reaction chamber can range from about 0.5 Torr to about 15 Torr, about 1 Torr to about 10 Torr, or about 2 Torr to about 5 Torr.

Next, during step 104, a layer including titanium nitride is deposited over at least a portion of the substrate. The layer including titanium nitride can be formed using, for example, a cyclic or ALD deposition process, in which a titanium precursor, such as, for example, titanium tetrachloride (TiCl4), titanium tetraiodide (TiI₄), tetrakis(dimethylamino)titanium (TDMAT), or tetrakis(diethylamido)titanium (TDEAT) and a reactant gas, such as a nitrogen-containing reactant gas are used.

In some embodiments of the disclosure, step 104 includes exposing the substrate to the titanium precursor for a time period of between about 0.01 seconds and about 60 seconds, between about 0.05 seconds and about 10 seconds, or between about 0.1 seconds and about 5.0 seconds. During this phase of step 104, a flow rate of the titanium precursor and a carrier gas may be greater than 0 and less than 2000 sccm, or less than 800 sccm—for example, the flow rate of the titanium precursor may range from about 1 to about 2000 sccm, from about 5 to about 1500 sccm, or from about 10 to about 1000 sccm, or from about 325 sccm to about 800 sccm.

Step 104 may include a sub step of purging the reaction chamber. For example, excess titanium precursor and reaction byproducts (if any) may be removed from the surface of the substrate and/or the reaction chamber, e.g., by pumping and/or with an inert gas. In some embodiments of the disclosure, the purge process may comprise a purge cycle wherein the substrate surface is purged for a time period of less than approximately 15.0 seconds, or less than approximately 10.0 seconds, or even less than approximately 5.0 seconds. Excess titanium precursor and any possible reaction byproducts may be removed with the aid of a vacuum, generated by a pumping system in fluid communication with the reaction chamber.

As noted above, step 104 can also include introducing a nitrogen reactant gas into the reaction chamber—e.g., after the purge sub step noted above. The nitrogen reactant gas may comprise at least one of nitrogen (N₂), ammonia (NH₃) hydrazine (N₂H₄), a hydrazine derivate. In some embodiments of the disclosure, a plasma may be generated by one or more of a direct plasma, a remote plasma, or a microwave plasma to form excited nitrogen-containing species. In certain embodiments of the disclosure, the plasma may be generated remotely by a microwave source.

Step 104 can include an additional purge sub step to remove, for example, excess nitrogen species and reaction byproducts (if any) from the surface of the substrate and/or reaction chamber, e.g., by pumping and/or with an inert gas. In some embodiments of the disclosure, the additional purge process may comprise a purge cycle wherein the substrate surface is purged for a time period of less than approximately 15.0 seconds, or less than approximately 10.0 seconds, or even less than approximately 5.0 seconds.

To further increase the oxygen scavenging properties of structures, the titanium nitride layer can be doped (e.g., with a doping level of about 0.5 to about 20, or about 2 to about 15, or about 5 to about 10 atomic percent of one or more of silicon, aluminum, tantalum, lanthanum, hafnium, and tungsten). The doping can be achieved by, for example, co-flowing a suitable dopant precursor with the titanium precursor, the reactant or other precursor, and/or by performing a separate ALD or cyclic deposition process to form a film comprising one or more of the group of silicon, aluminum, tantalum, lanthanum, hafnium, and tungsten.

As illustrated in FIG. 1, step 104 can be repeated a number of times (loop 112) prior to proceeding to step 106. For example, step 104 can be repeated 0, 5, 10, 50, or 200 times before proceeding to step 106.

Next, during step 106, a layer including silicon nitride is deposited over at least a portion of a titanium nitride layer formed during step 104. The silicon nitride layer can be formed using, for example, a (e.g., thermal) cyclic or ALD deposition process, in which a silicon halide precursor, such as, for example, as SiCl₄, SiBr₄, or a chlorosilane precursor, such as SiHCl₃, SiH₂Cl₂, or a silane precursor, such as SiH₄, Si₂H₆, or Si₃H₈, and a nitrogen reactant gas are used.

As noted above, steps 104 and 106 are performed within the same reaction chamber. Step 106 can be performed at the same pressure and/or same temperature as step 104, such as any of the temperatures and pressures noted above in connection with step 104.

In some embodiments of the disclosure, step 106 may comprise contacting the silicon precursor to the substrate for a time period of between about 0.01 seconds and about 60 seconds, between about 0.05 seconds and about 10 seconds, or between about 0.1 seconds and about 5.0 seconds. During this step, a flow rate of the silicon precursor may be greater than 0 and less than 2000 sccm, or less than 1000 sccm, or even less than 500 sccm. For example, the flow rate can be between about 100 and about 500 sccm.

Step 106 may include a sub step of purging the reaction chamber. For example, excess silicon precursor and reaction byproducts (if any) may be removed from the surface of the substrate, e.g., by pumping and/or with an inert gas. In some embodiments of the disclosure, the purge process may comprise a purge cycle wherein the substrate surface is purged for a time period of less than approximately 15.0 seconds, or less than approximately 10.0 seconds, or even less than approximately 5.0 seconds. Excess silicon precursor and any possible reaction byproducts may be removed with the aid of a vacuum, generated by a pumping system in fluid communication with the reaction chamber.

As noted above, step 106 can also include introducing a nitrogen reactant gas into the reaction chamber—e.g., after the purge sub step noted above. The nitrogen reactant gas may comprise at least one of nitrogen (N₂), ammonia (NH₃) hydrazine (N₂H₄), a hydrazine derivate. The nitrogen reactant can be the same as or different from the nitrogen reactant gas used during step 104. In some embodiments of the disclosure, a plasma may be generated by one or more of a direct plasma, a remote plasma, or a microwave plasma to form excited nitrogen-containing species. In certain embodiments of the disclosure, the plasma may be generated remotely by a microwave source.

Step 106 can include an additional purge sub step to remove, for example, excess nitrogen species and reaction byproducts (if any) from the surface of the substrate and/or reaction chamber, e.g., by pumping and/or with an inert gas. In some embodiments of the disclosure, the purge process may comprise a purge cycle wherein the substrate surface is purged for a time period of less than approximately 15.0 seconds, or less than approximately 10.0 seconds, or even less than approximately 5.0 seconds.

Step 106 can be repeated a number of times (loop 114) prior to optionally repeating step 104 or ending the method (step 108). For example, step 106 can be repeated, for example about 20 to about 40 times before proceeding to step 104 or 108.

In accordance with various examples of the disclosure, step 106 is self-limiting at a silicon nitride thickness of about 0.5 to about 2 Angstroms or of about 1 Angstrom. It was observed that a relatively thin—e.g., less than 1 or 2 Angstroms—silicon nitride film provided desired film properties, namely mitigation of oxidation of the underlying titanium nitride layer, while not significantly increasing the resistivity of a compound film comprising the silicon nitride and the titanium nitride.

Although not illustrated in FIG. 1, methods in accordance with the present disclosure can additionally include the step of forming a passivation layer, forming an interface layer, and/or forming a high dielectric material layer underlying the titanium nitride layer (e.g., overlying a semiconductor layer/channel region). A method of forming an exemplary passivation or interface layer can include using H₂S or hydrazine for pretreatment. A more detailed description of an exemplary passivation process is disclosed in U.S. Pat. No. 9,911,676, entitled System and Method for Gas-Phase Passivation of a Semiconductor Surface, issued Mar. 6, 2018, the relevant contents of which are hereby incorporated herein by reference to the extent such contents do not conflict with the present disclosure. Additionally, or alternatively, a thin layer of silicon with a silicon oxide cap can be used as an interface/passivation layer between a semiconductor and the high dielectric constant material.

Additionally, or alternatively, method of forming a structure 100 can include a hydrogen plasma treatment after step 106 and before repeating or ending the method. The hydrogen plasma treatment process can include exposing the film deposited during step 106 (e.g., after one or more cycles) to excited hydrogen species formed using a direct or remote plasma apparatus.

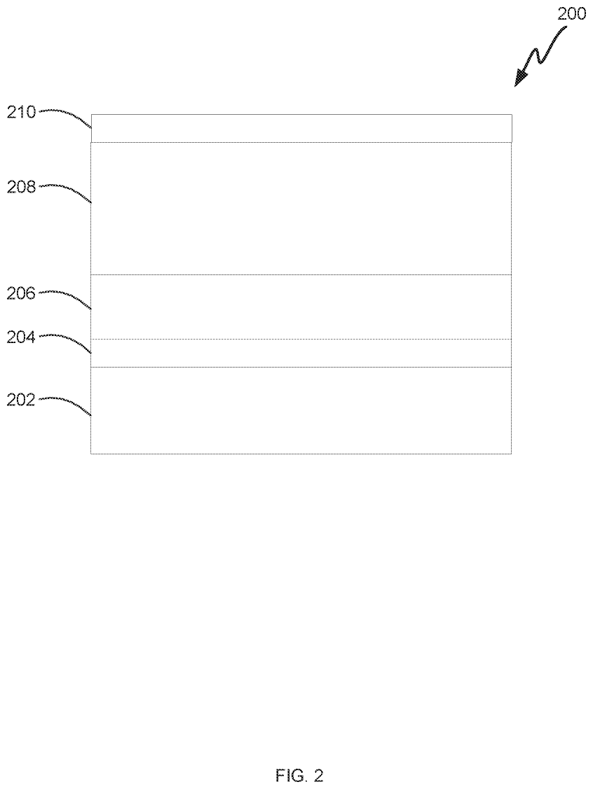

Turning now to FIG. 2, a structure 200, formed according to exemplary methods described herein, is illustrated. Structure 200 includes a first layer 202, a passivation and/or interface layer 204, a high dielectric constant material layer 206, a titanium nitride layer 208, and a silicon nitride layer 210.

First layer 202 can be or form part of a substrate. By way of examples, first layer 202 includes a high-mobility semiconductor material, such as SixGe1-x, where x is greater than 0 and less than 1, or about (e.g., greater than) 0 to about 0.25, or about 0.25 to about 0.5, or about 0.5 to about 0.75. First layer 202 can be or form part of, for example, a channel region of an MOS device.

Passivation and/or interface layer 204 can be used to further improve EOT and/or reduce Dit. An exemplary passivation and/or interface layer includes H₂S or hydrazine pretreated interface. Additionally, or alternatively, the passivation and/or interface layer can include thin layers (e.g., less than ˜1 nm) of silicon and silicon oxide.

Titanium nitride layer 208 can be or include a titanium nitride layer formed using techniques described above. In some embodiments of the disclosure, the titanium nitride film formed by exemplary method 100 may have a thickness from about 5 Angstroms to about 50 Angstroms, or about 10 Angstroms to about 30 Angstroms. In some embodiments, a titanium nitride film deposited according to some of the embodiments described herein may have a thickness greater than about 5 Angstroms, or greater than about 10 Angstroms, or greater than about 20 Angstroms, or greater than about 50 Angstroms. In some embodiments, a titanium nitride film, e.g., a titanium nitride film, deposited according to some of the embodiments described herein may have a thickness of less than about 50 Angstroms, or less than about 30 Angstroms, or less than about 20 Angstroms, or less than about 15 Angstroms, or less than about 10 Angstroms, or even less than about 5 Angstroms. By way of particular examples, a thickness of the titanium nitride film is about 20 Angstroms.

Silicon nitride layer 210 can be formed using, for example, techniques as described herein. In some embodiments of the disclosure, the silicon nitride film formed by exemplary process 100 may have a thickness from greater than 0 Angstroms to about 10 Angstroms, to about 5 Angstroms, to about 2 Angstroms, or to about 1 Angstrom.

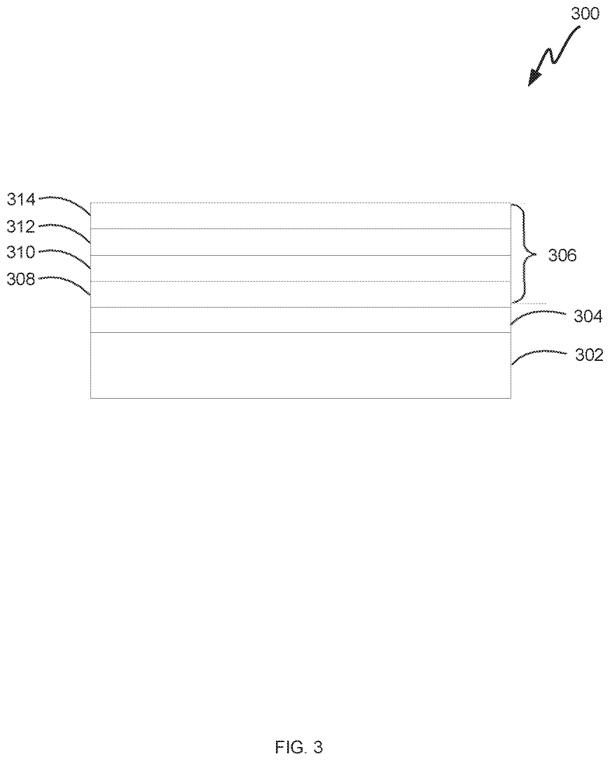

FIG. 3 illustrates another structure that can be formed, at least in part, using techniques described herein. Structure 300 includes a first layer or substrate 302, a metal carbide layer 304, and a TiN/SiN laminate 306, including one or more TiN layers 308, 312 and one or more SiN layers 310, 314.

Substrate 302 can include any of the substrate material described herein. By way of example, substrate 302 can include a semiconductor layer, a passivation and/or interface layer, and a high dielectric constant material layer as described above.

Metal carbide layer 304 can be or include, for example, titanium carbide or titanium aluminum carbide. A thickness of the metal carbide layer 304 can vary according to application. By way of examples, metal carbide layer 304 can be about 1.0 to about 30 or about 2.0 to about 20 or about 5.0 to about 15 thick. However, the disclosure is not restricted to such number of layers or layer thicknesses, unless otherwise noted. Metal carbide layer 304 can be, for example, a work function layer of a MOS device.

Laminate structure 306 includes at least one titanium nitride layer 308 and at least one silicon nitride layer 314. Laminate structure 306 can include a layer of titanium nitride 308 at the bottom of the structure and a silicon nitride layer 314 at the top of the structure to prevent or mitigate oxidation of the titanium nitride layer(s). Each titanium nitride layer 308, 312 and each silicon nitride layer 310, 314 can be formed using techniques described herein, and may preferably be formed at lower temperatures, e.g., in the range of about 390° C. to about 500° C.

Although exemplary embodiments of the present disclosure are set forth herein, it should be appreciated that the disclosure is not so limited. Various modifications, variations, and enhancements of the apparatus, assemblies, and systems set forth herein may be made without departing from the spirit and scope of the present disclosure.

Unless otherwise stated, the subject matter of the present disclosure includes all novel and nonobvious combinations and subcombinations of the various systems, components, and configurations, and other features, functions, acts, and/or properties disclosed herein, as well as any and all equivalents thereof.

What is claimed is:

1. A method of forming a structure including a silicon nitride layer, the method comprising the steps of:
providing a substrate in a reaction chamber;
forming a layer comprising titanium nitride overlying the substrate in the reaction chamber; and
forming a layer comprising silicon nitride overlying the layer comprising titanium nitride in the reaction chamber,
wherein the step of forming the layer comprising titanium nitride and the step of forming the layer comprising silicon nitride are performed within the reaction chamber.

2. The method of claim 1, wherein the step of forming the layer comprising titanium nitride and the step of forming the layer comprising silicon nitride are performed without an intervening step of exposing the substrate to a substrate transfer region of a processing tool.

3. The method of claim 1, wherein the step of forming the layer comprising titanium nitride and the step of forming the layer comprising silicon nitride are performed without an intervening step of exposing the substrate to a vacuum break.

4. The method of claim 1, wherein the layer comprising silicon nitride has a thickness between greater than 0 and about 2 Angstroms.

5. The method of claim 1, wherein a temperature during the step of forming the layer comprising titanium nitride is between about 350° C. to about 650° C.

6. The method of claim 5, wherein a temperature during the step of forming the layer comprising silicon nitride is between about 350° C. to about 650° C.

7. The method of claim 1, wherein the layer comprising titanium nitride is formed overlying a layer comprising titanium carbide.

8. The method of claim 1, wherein the layer comprising titanium nitride is formed overlying a layer comprising titanium aluminum carbide.

9. The method of claim 1, wherein the layer comprising titanium nitride is formed overlying a high dielectric constant material layer.

10. The method of claim 9, wherein the high dielectric constant material comprises one or more of hafnium oxide, lanthanum silicate, aluminum silicate, zirconium oxide, hafnium silicate, zirconium silicate, and niobium oxide

11. The method of claim 1, wherein the step of forming the layer comprising silicon nitride comprises a cyclic deposition process.

12. The method of claim 1, wherein the step of forming the layer comprising silicon nitride comprises an atomic layer deposition process.

13. The method of claim 1, wherein the substrate comprises a channel region comprising silicon germanium.

14. The method of claim 1, further comprising a step of forming a passivation layer between a silicon germanium channel region and a high dielectric constant material.

15. The method of claim 1, wherein the titanium nitride layer further comprises a dopant selected from the group consisting of silicon, aluminum, tantalum, lanthanum, hafnium, and tungsten.

16. The method of claim 1, further comprising forming a laminate structure by repeating the steps of forming the layer comprising titanium nitride and forming the layer comprising silicon nitride, wherein the laminate structure is capped with the layer comprising silicon nitride.

17. A structure formed according to the method of claim 1.

18. The structure of claim 17, comprising:
a channel region comprising silicon germanium.

19. The structure of claim 18, further comprising:
a high dielectric constant material overlying the channel region.

20. A method of forming a structure including a silicon nitride layer, the method comprising the steps of:
providing a substrate in a reaction chamber;
forming a layer comprising titanium nitride overlying the substrate in the reaction chamber using a cyclic deposition process; and
forming a layer comprising silicon nitride using another cyclic deposition process overlying the layer comprising titanium nitride in the reaction chamber,
wherein the step of forming the layer comprising titanium nitride and the step of forming the layer comprising silicon nitride are performed within the reaction chamber without a vacuum break.
